(19) United States
(12) Patent Application Publication
(10) Pub. No.: US 2023/0420379 A1
(43) Pub. Date: Dec. 28, 2023

(54) INTEGRATED CIRCUIT PACKAGE WITH PSEUDO-STRIPLINE ARCHITECTURE

(71) Applicant: Intel Corporation, Santa Clara, CA (US)

(72) Inventors: Eng Huat Goh, Ayer Itam (MY); Seok Ling Lim, Kulim (MY); Hazwani Jaffar, Kepala Batas (MY); Yean Ling Soon, Butterworth (MY)

(73) Assignee: Intel Corporation, Santa Clara, CA (US)

(21) Appl. No.: 17/848,059

(22) Filed: Jun. 23, 2022

(51) Int. Cl. H01L 23/538; H01L 21/48; H01L 23/498; H01L 23/552; H01L 23/66

(52) U.S. Cl. CPC H01L 23/5386; H01L 21/4853; H01L 21/486; H01L 23/49816; H01L 23/49833; H01L 23/49838; H01L 23/5381; H01L 23/5385; H01L 23/552; H01L 23/66; H01L 21/4857; H01L 23/49822; H01L 2223/6616; H01L 2223/6627; H01L 2223/6677; H01L 24/08

(57) ABSTRACT

IC device package routing with metallization features comprising a pseudo-stripline architecture in which the stripline structure is provisioned, in part, by a routing structure separate from routing within the package substrate. A signal route within top metallization level of a package substrate may be electrically shielded, in part, with a metallization feature within a redistribution layer (RDL) of a routing structure that couples one or more IC chips to the package substrate. Accordingly, a package substrate may have fewer levels of metallization, reduced thickness, and/or lower cost while the IC device package still offers excellent EMI performance.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical contacts suitable for further connecting to other IC chips and a host component, such as a printed circuit board (PCB) or interposer. In the IC industry, the process of fabricating a package is often referred to as packaging, or assembly.

Next generation multi-chip packaging (MCP) demands greater interconnect density to support evolving systems-in-package and/or bandwidth-intensive applications. In a high bandwidth architecture, for example, multiple IC dies assembled on the package in proximity may need to be electrically interconnected through fine routing layers that include lines (i.e., traces) embedded within an interconnect level of the packaging that is adequately shielded from electromagnetic interference (EMI).

Along with greater demands on IC device package routing, there is also an ongoing effort to reduce package substrate metallization level count. With fewer levels, IC device package substrates are thinner, cost less per unit, and/or the total number of substrates that can be produced with a given manufacturing capacity is increased. In many IC device package architectures, the minimum package substrate metallization layer count is dictated by input/output (I/O) routing of memory circuitry. For example, a dynamic random-access memory (DRAM) with a double data rate (e.g., DDR4, DDR5, etc.) often has a bump pattern requiring two package metallization levels to breakout the signal I/O. In FIG. 1A, for example, an IC die 103 data (e.g., DQ) signal I/O S1 and S2 are coupled with a conventional package substrate 101 having a stripline transmission line architecture for two “Data” routing levels. In the illustrated stripline-stripline architecture, two metallization levels (e.g., 2F and 4F) carrying DDR data signals are interleaved with three levels of ground (Vₛₛ) planes. As such, there is good electrical shielding above and below lateral signal routes 110 and 120. However, package 101 therefore requires at least five front-side (F) routing metallization levels. For a symmetrical build-up, package 101 has a total of ten metallization levels with the back-side (B) levels including, for example, power (V_{dd}), routing and host component interconnect interfaces (e.g., to receive a ball grid array).

FIG. 1B illustrates IC die 103 coupled to another conventional package substrate 102, which has only eight metallization levels. To achieve the reduction in metallization levels relative to package substrate 101, data signals S1 are conveyed on the top package metallization level (5F) with a microstrip architecture rather than a stripline architecture. In the absence of a top-level ground plane, such microstrip package routing architectures generally offer less protection from electromagnetic interference (EMI) and/or other signal interference (SI) than stripline architectures. Accordingly, there may be RF emissions from lateral signal route 120, and/or RF emissions may disturb signals on lateral signal route 120. due to greater risk of suffering IC device failures attributable to EMI and/or other SI, a microstrip architecture is generally not an option for the highest speed I/O signals (e.g., beyond ˜4300 MT/s).

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views labeled “cross-sectional” and “plan” correspond to orthogonal planes within a cartesian coordinate system. Thus, cross-sectional views are taken in the x-z plane, and plan views are taken in the x-y plane. Where appropriate, drawings are labeled with axes to indicate the orientation of the figure. Further, where considered appropriate, reference labels have been repeated among the figures to indicate corresponding or analogous elements. In the figures:

FIGS. 1A and 1B illustrate cross-sectional views of IC die package routing architectures, in accordance with convention;

FIG. 2A illustrates a cross-sectional view through an IC device package with a pseudo-stripline signal routing architecture, in accordance with some embodiments;

FIG. 2B illustrates a plan view of the IC device package illustrated in FIG. 2A, in accordance with some embodiments;

FIG. 3 illustrates a system including an IC device package with a pseudo-stripline signal routing architecture, in accordance with some embodiments;

FIG. 4 illustrates a mobile computing platform and a data server machine employing pseudo-stripline package signal routing, in accordance with embodiments; and

FIG. 5 is a functional block diagram of an electronic computing device, in accordance with some embodiments.

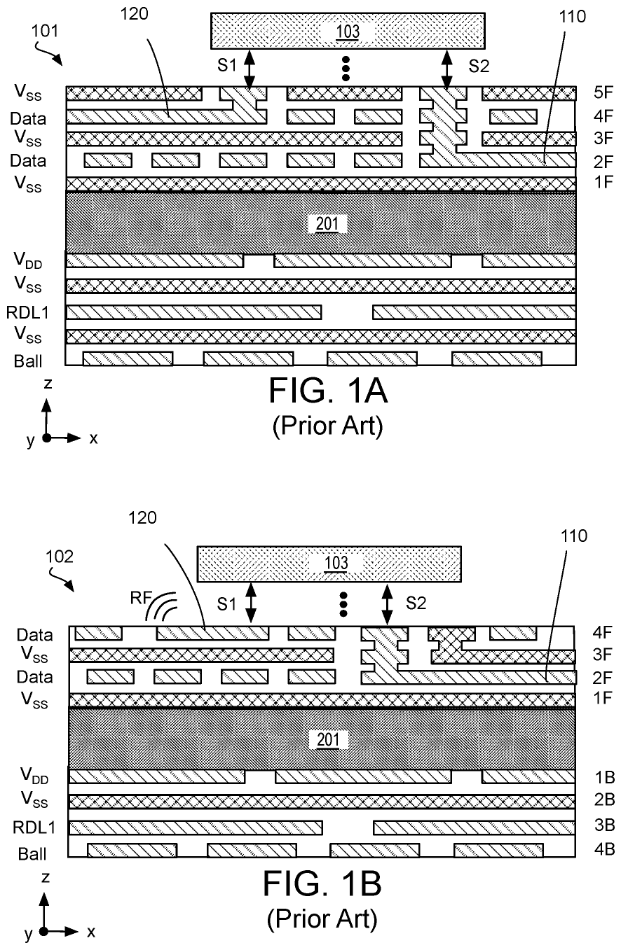

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

IC device package routing with metallization features comprising a pseudo-stripline architecture are described below. The architecture generally comprises the augmentation of a signal route within top metallization level of a package substrate with a metallization feature of a redistribution layer (RDL) in a routing structure that couples an IC chip to the package substrate. Absent augmentation, the lateral signal route within the top metallization level may have a microstrip architecture. However, in accordance with embodiments herein this microstrip architecture of the package substrate is augmented into a hybrid architecture having an additional ground plane within the routing structure assembled to the package substrate. This hybrid transmission line architecture is referred to herein as a pseudo-stripline architecture as the stripline structure is provisioned, in part, by a routing structure separate from the package substrate. Accordingly, the package substrate may have fewer levels of metallization, lower thickness, and/or lower cost.

For multi-chip packages interconnected with a routing structure separate from the package substrate, the ground plane feature needed to provide a pseudo-stripline architecture may be implemented within an existing metallization level of the routing structure at little additional cost. For exemplary embodiments, as described further below, the routing structure may comprise an extension region spanning an arbitrary distance beyond an edge of one or more IC chips. Ground plane features may be defined within this extension region to shield a signal fan-out region within the package substrate.

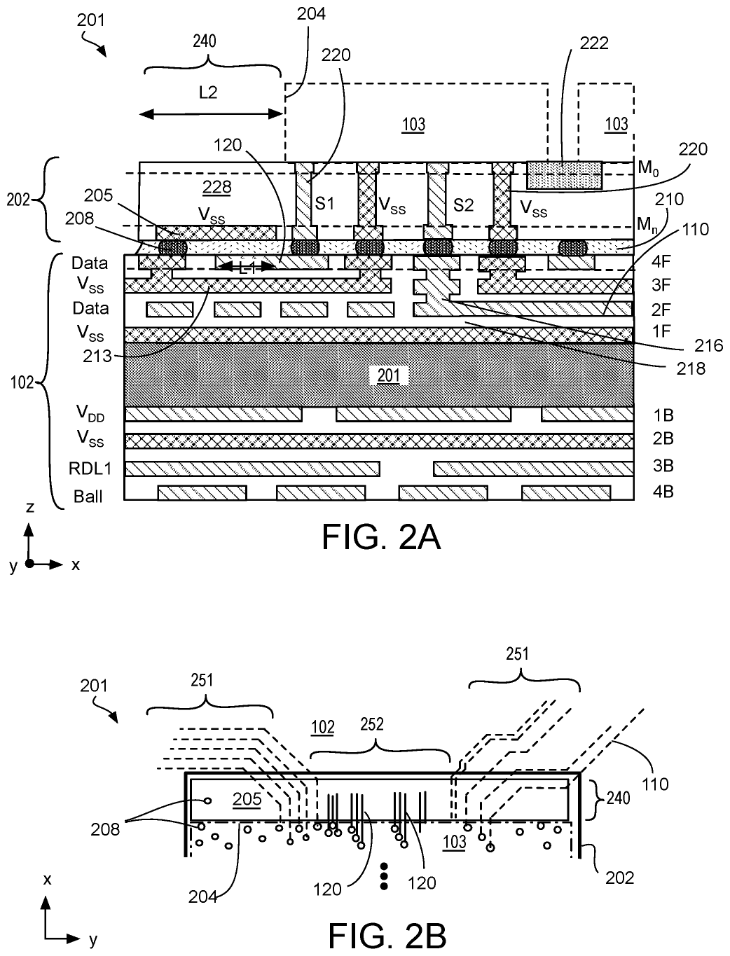

FIG. 2A illustrates a cross-sectional view through an IC device package 201 with a pseudo-stripline signal routing architecture, in accordance with some embodiments. IC device package 201 includes package substrate 102 and a routing structure 202. A bottom side of routing structure 202 is coupled to a top side of package substrate 102 through a plurality of interconnects 208. A top side of routing structure 202 is to couple to one or more IC chip 103, illustrated in dashed line as IC device package 201 may be fully assembled with IC chips 103, or merely a preform suitable for further assembly with IC chips 103.

In this example, package substrate 102 again comprises core 201. Alternatively, a package substrate may be “coreless.” In the absence of core 201, a package substrate may rely on a sacrificial carrier to mechanically support the package build-up materials. Core 201 may be any preform comprising any material with mechanical rigidity and/or stiffness sufficient to serve as a platform for building up layers of package metallization comprising front-side line metallization levels 1F, 2F, 3F and 4F and via metallization 216 between the line metallization levels (e.g., 2F and 3F). Such a build-up may be performed concurrently on a front (chip or die) side and a back (land) side of the core 201. In this example, package substrate 102 includes back-side line metallization levels 1B, 2B, 3B and 4B. Although not illustrated, via metallization may vertically interconnect features in the various back-side line metallization levels. Any number of conductive through holes (not depicted) may also pass through core 201, electrically coupling one or more front-side line metallization levels 1F-4F with one or more back-side line metallization levels 1B-4B. Metallization features within package substrate 102 may have been formed with an additive or semi-additive process, for example. In some exemplary embodiments, metallization features within package substrate 102 comprise one or more layers of predominantly copper. However, other conductive materials are also possible.

Package substrate metallization is embedded within one or more layers of package substrate insulator 218. In exemplary embodiments, package substrate insulator 218 comprises an organic dielectric material (e.g., comprising a polymer). Package substrate insulator 218 may comprise an epoxy resin, phenolic-glass, or a resinous film such as the GX-series films commercially available from Ajinomoto Fine-Techno Co., Inc.). Exemplary epoxy resins include an acrylate of novolac such as epoxy phenol novolacs (EPN), or epoxy cresol novolacs (ECN). In some specific examples, package substrate insulator 218 is a bisphenol-A epoxy resin, for example including epichlorohydrin. In other examples, package substrate insulator 218 includes bisphenol-F epoxy resin (with epichlorohydrin). In other examples, package substrate insulator 218 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, package substrate insulator 218 includes glycidylamine epoxy resin, such as triglycidyl-p-aminophenol (functionality 3) and N,N,N′,N′-tetraglycidyl-bis-(4-aminophenyl)-methane (functionality 4).

In the example illustrated, front-side line metallization levels 1F-4F are separated into two data signal (e.g., “Data”) routing planes (2F and 4F) and two ground reference (e.g., “Vₛₛ”) planes (1F and 2F). For clarity, data planes and ground reference planes are illustrated with different line shading. Signal route 110 extends laterally (e.g., along x-axis) within the data plane 2F. Signal route 110 is between the 1F and 3F Vₛₛ planes of metallization and therefore is a transmission line with a stripline architecture. Package substrate 102 further comprises signal route 120 that extends laterally (e.g., along x-axis) within data plane 4F. Data plane 4F is the top metallization level of package substrate 201 and therefore only partially shielded by a metallization feature 213 located within the 3F Vₛₛ plane.

In accordance with embodiments herein, routing structure 202 comprises one or more metallization features that augment or complete the transmission line architecture for signal route 120. In the example illustrated, routing structure 202 comprises a metallization feature 205 that extends over at least a portion of signal route 120. Metallization feature 205 is coupled to a ground reference Vₛₛ plane (e.g., 3F) of package substrate 102. As such, over at least the signal route length L1, signal route 120 has a pseudo-stripline architecture that includes both metallization feature 213 and metallization feature 205. Although not part of the same package component, the metallization features 213 and 205 together are EMI shielding above and below signal route 120.

Routing structure 202 includes one or more layers of package insulator 228. Package insulator 228 may have any of the compositions described above for package substrate insulator 218. In some embodiments, package insulator 228 has substantially the same composition as package substrate insulator 218. In other embodiments, insulators 218 and 228 have different compositions. Metallization features within routing structure 202 may comprise predominantly copper, or any other suitably conductive material. Metallization features within routing structure 202 may therefore have substantially the same composition as metallization features within package substrate 201. Metallization features within routing structure 202 may also have a different composition than metallization features within package substrate 201.

Routing structure 202 may be referred to as an RDL interposer and may support multi-chip/chiplet package-level aggregation by interfacing any number of IC chips to each other and/or to a single package substrate 102. Routing structure 202 may be fabricated, for example, according to wafer-level packaging (WLP) techniques where many IC chips are packaged in parallel while on a sacrificial/temporary carrier or panel substrate.

In some embodiments routing structure 202 includes a means of coupling together two or more adjacent IC chips 103. In the illustrated example, routing structure 202 hosts an interconnect bridge preform 222 embedded within routing structure 202 that is to provide multi-chip interconnect routing. Interconnect bridge preform 222 may, for example, comprise a semiconductor chiplet with high density interconnect circuitry fabricated with a back-end-of-line IC fabrication process. In other embodiments, routing structure 202 may include one or more levels of routing metallization that interconnects data signal I/O of adjacent IC chips. I/O of IC 103 chips not interconnected to each other by routing structure 202 may be spatially redistributed by package substrate 201 from a feature pitch minimum associated with interconnects 208.

In FIG. 2A, routing structure 202 includes metallization features 220 that route signals (e.g., S1, S2, etc.) between IC chip 103 and package substrate 102 through interconnects 208. Other metallization features 220 couple IC chip 103 to the package ground plane Vₛₛ, power V_{dd}, etc. Interconnects 208 may be solder features, for example. Solder features may be microbumps, pillars, or posts that may be at least partially reflowed during an assembly process. Alternatively, interconnects 208 may be metal features of routing structure 202 that are directly bonded (e.g., compression bonded) to metal features of package substrate 201.

In the example illustrated, signal S1 is interconnected to lateral signal route 120 while signal S2 is routed to interconnect to lateral signal route 110. Although the lateral redistribution or fan-out routing for signals S1 and S2 occurs within package substrate 102, routing structure 202 supports shielding of the lateral routing runs by including an extension region 240 beyond an edge 204 of IC chip 103. In the illustrated example, extension region 240 spans a lateral length L2 in the same direction as the lateral length L1. Metallization feature 205 occupies at least some portion of extension region 240 and covers at least some portion of the lateral length L1 of signal route 120. Metallization features within any level of metallization within routing structure 202 may be coupled to the package ground plane as a means of shielding signal route 120. In some advantageous embodiments, metallization feature 205 is within a metallization level of routing structure 202 that is most proximal to package substrate 102. In the illustrated example where the metallization level most proximal to IC chip 103 is a first level (M₀), metallization feature 205 is within a last metallization level (Mₙ). As such, metallization feature 205 is substantially coplanar with an array of metallization features within metallization level Mₙ that directly contact the array of interconnects 208.

The pseudo-stripline architecture comprising signal route 120 between grounded metallization features 205 and 213 spans any gap in the z-dimension between routing structure 202 and package substrate 102. In exemplary embodiments, a package underfill dielectric 210 is between routing structure 202 and package substrate 102. Package underfill dielectric 210 may, for example, have a different composition than at least one of insulators 218 or 228. In some examples, package underfill dielectric 210 is a cured (e.g., thermoset) resin or polymer comprising epoxy and/or silicone. Package underfill dielectric 210 may further surround interconnects 208, substantially as illustrated in FIG. 2A.

FIG. 2B illustrates a plan view of a portion of IC device package 201, in accordance with some embodiments. In FIG. 2B, portions of some edges of an IC chip 103 are illustrated in dotted-dashed line. One of the illustrated edges is IC chip edge 204 introduced in FIG. 2A. The array of package substrate interconnects 208 are further illustrated in FIG. 2B with at least a majority of the array being within an area of IC chips 103. A heavy solid line illustrates edges of a portion of routing structure 202.

In the example illustrated, metallization feature 205 is a substantially contiguous sheet of metal occupying most of extension region 240. Metallization feature 205 may be coupled to one or more interconnects 208 further coupled to the package substrate Vₛₛ. Metallization feature 205 has a length (e.g., in the y-dimension) that spans at least a fan-out region 252 of IC chip edge 204 where a plurality of signal routes 120 run laterally from IC chip edge 204. Each of the plurality of signal routes 120 are illustrated in solid line as also being within a top metallization level of package substrate 102. In the illustrated example, all signal routes 120 within fan-out portion 252 are relatively short runs terminating within extension region 240. Metallization feature 205 substantially covers each of the signal routes within fan-out region 252, providing a contiguous conductive material sheet over all signal routes 120 that completes a pseudo stripline transmission line architecture for each of them.

Notably, by optimizing the signal route length L1 within fan-out region 252, extension region 240 may have a length L2 (FIG. 2A) of around one millimeter. Such a small extension need not significantly impact the form factor of IC device package 201 for designs that are bottom side fit and/or routing limited rather than top side fit limited. Package substrate 102 may extend an arbitrary distance beyond routing structure 202, for example with fan-out regions 251 extending well beyond metallization feature 205 anywhere all signal routes are substantially the same as signal route 110. Such routes are illustrated in FIG. 2B with a dashed line as being within a lower metallization level that has a microstrip architecture fully supported by ground planes of package substrate 102.

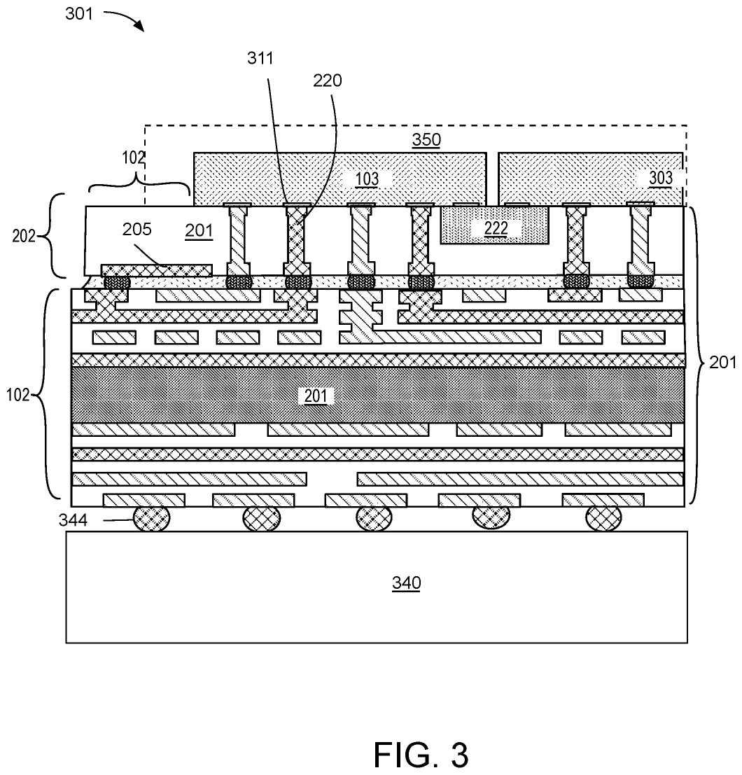

FIG. 3 illustrates a system 301 including pseudo-stripline package routing, in accordance with some embodiments. System 301 includes two IC chips 103 and 303 coupled to each other through IC device package 201. In exemplary embodiments, at least IC chip 103 includes electronic memory circuitry, such as, but not limited to, dynamic random-access memory (DRAM). In some further embodiments, at least IC die 303 includes microprocessor circuitry, graphics processing circuitry, or heterogeneous processing circuitry. Microprocessor circuitry may be operable, for example, to execute a real-time operative system (RTOS). In some further embodiments, at least IC chip 303 is operable to execute one or more layers of a software stack that controls radio (wireless) functions. In other embodiments, both of IC chips 103 and 303 include memory circuitry, or both of IC chips 103 and 303 include microprocessor circuitry.

In the example depicted in FIG. 3, IC chips 103 and 303 included interconnect interfaces 311 that are each coupled to a metallization feature of routing structure 202. IC chip interconnect interfaces 311 electrically couple IC chip 103 to ground Vₛₛ planes, and various signal routes. IC chip interconnect interfaces 311 are in direct contact with metallization features within a level of routing structure 202 that is most distal from package substrate 102. IC chip interconnect interfaces 311 may, for example, be directly bonded to routing metallization features 220, or routing metallization features 220 may have been directly formed upon IC chip interconnect interfaces 311.

In the illustrated example, system 301 includes an interconnect bridge chip 222 coupled to one or more IC chip interconnect interfaces 311 of both IC chip 103 and IC chip 303, for example interconnecting at least some data signal I/Os (e.g., DQs) of IC chip 103 to at least some data signal I/Os of IC chip 303. In other embodiments, instead of an interconnect bridge chip, routing structure 202 comprises metallization features interconnecting IC die 103 to adjacent IC die 303.

System 301 includes a host component 304, such as a PCB or interposer, coupled to package substrate 102 through any suitable second level interconnects 344 (e.g., a ball grid array). Host component 304, may, for example, comprise a primary power supply that is to receive a mains electrical input and output one or more system power supply rails based on the mains input. In some embodiments, the package substrate ground Vₛₛ planes are coupled a ground reference of the power supply output. System 301 may further include one or more heat spreader, heat sink, or active cooling structure 350.

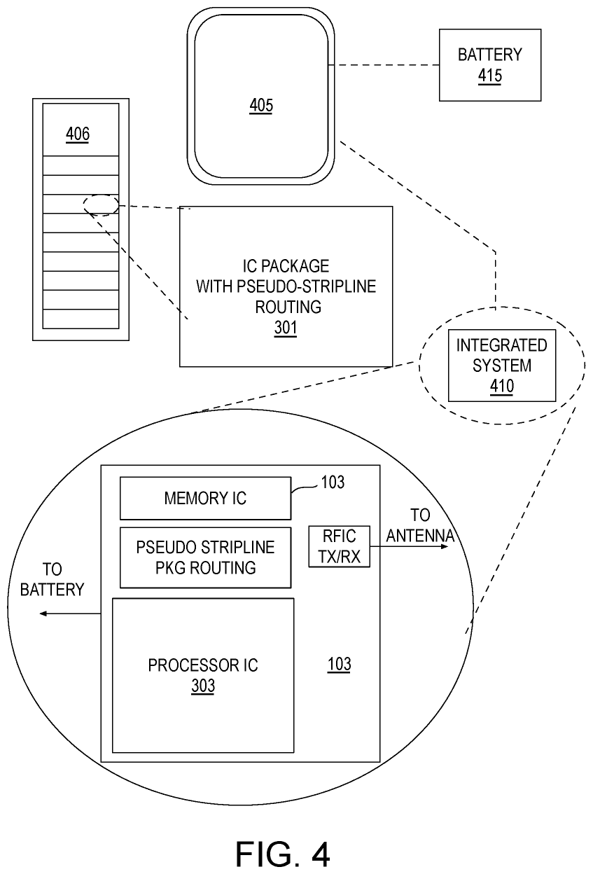

FIG. 4 illustrates a mobile computing platform and a data server machine employing package routing with a pseudo-stripline architecture, for example as described elsewhere herein. The server machine 406 may be any commercial server, for example including any number of high-performance computing platforms disposed within a rack and networked together for electronic data processing, which in the exemplary embodiment includes a packaged monolithic SoC. The mobile computing platform 405 may be any portable device configured for each of electronic data display, electronic data processing, wireless electronic data transmission, or the like. For example, the mobile computing platform 405 may be any of a tablet, a smart phone, laptop computer, etc., and may include a display screen (e.g., a capacitive, inductive, resistive, or optical touchscreen), a chip-level or package-level integrated system 410, and a battery 415.

As a system component within the server machine 406, a memory IC (e.g., RAM) chip 103 and a processor IC (e.g., a microprocessor, a multi-core microprocessor, baseband processor, or the like) chip 303 are interconnected through a pseudo-stripline routing structure, for example substantially as described elsewhere herein. One or more other IC chips may also be assembled upon package substrate 103. For example, a RF (wireless) integrated circuit (RFIC) including a wideband RF (wireless) transmitter and/or receiver (TX/RX) may be further interconnected to package substrate 103. Functionally, an RFIC may have an output coupled to an antenna to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

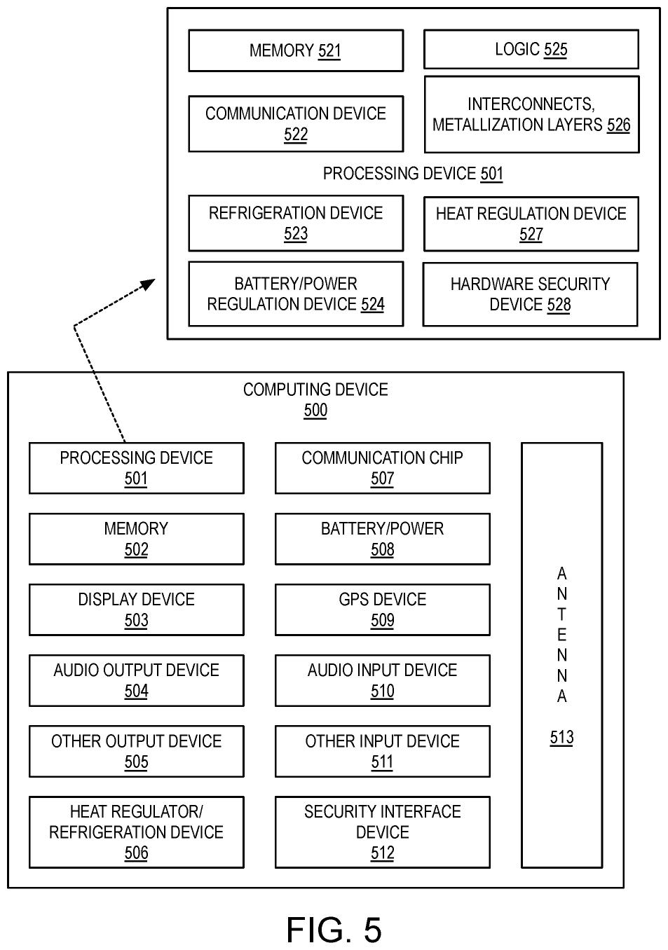

FIG. 5 is a block diagram of a cryogenically cooled computing device 500 in accordance with some embodiments. For example, one or more components of computing device 500 may include any of the devices or structures discussed elsewhere herein. Components illustrated in FIG. 5 as included in computing device 500 may be omitted or duplicated, as suitable for the application. In some embodiments, some or all the components included in computing device 500 may be attached to one or more printed circuit boards (e.g., a motherboard). In some embodiments, various ones of these components may be fabricated onto a single system-on-a-chip (SoC) die. Additionally, in various embodiments, computing device 500 may not include one or more of the components illustrated in FIG. 5, but computing device 500 may include interface circuitry for coupling to the one or more components. For example, computing device 500 may not include a display device 503, but may include display device interface circuitry (e.g., a connector and driver circuitry) to which display device 503 may be coupled.

Computing device 500 may include a processing device 501 (e.g., one or more processing devices). As used herein, the term processing device or processor indicates a device that processes electronic data from registers and/or memory to transform that electronic data into other electronic data that may be stored in registers and/or memory. Processing device 501 may include a memory 521, a communication device 522, a refrigeration/active cooling device 523, a battery/power regulation device 524, logic 525, interconnects 526, a heat regulation device 527, and a hardware security device 528.

Processing device 501 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 501 may include a memory 502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 521 includes memory that shares a die with memory 502. This memory may be used as cache memory and may include embedded dynamic random-access memory (eDRAM) or spin transfer torque magnetic random-access memory (STT-M RAM).

Computing device 500 may include a heat regulation/refrigeration device 506. Heat regulation/refrigeration device 506 may maintain processing device 501 (and/or other components of computing device 500) at a predetermined low temperature during operation. This predetermined low temperature may be any temperature discussed elsewhere herein.

In some embodiments, computing device 500 may include a communication chip 507 (e.g., one or more communication chips). For example, the communication chip 507 may be configured for managing wireless communications for the transfer of data to and from computing device 500. The term “wireless” and its derivatives may be used to describe circuits, devices, systems, methods, techniques, communications channels, etc., that may communicate data with modulated electromagnetic radiation through a nonsolid medium.

Communication chip 507 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1307 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 507 may operate in accordance with other wireless protocols in other embodiments. Computing device 500 may include an antenna 513 to facilitate wireless communications and/or to receive other wireless communications (such as AM or FM radio transmissions).

In some embodiments, communication chip 507 may manage wired communications, such as electrical, optical, or any other suitable communication protocols (e.g., the Ethernet). As noted above, communication chip 507 may include multiple communication chips. For instance, a first communication chip 507 may be dedicated to shorter-range wireless communications such as Wi-Fi or Bluetooth, and a second communication chip 507 may be dedicated to longer-range wireless communications such as GPS, EDGE, GPRS, CDMA, WiMAX, LTE, EV-DO, or others. In some embodiments, a first communication chip 507 may be dedicated to wireless communications, and a second communication chip 507 may be dedicated to wired communications.

Computing device 500 may include battery/power circuitry 508. Battery/power circuitry 508 may include one or more energy storage devices (e.g., batteries or capacitors) and/or circuitry for coupling components of computing device 500 to an energy source separate from computing device 500 (e.g., AC line power).

Computing device 500 may include a display device 503 (or corresponding interface circuitry, as discussed above). Display device 503 may include any visual indicators, such as a heads-up display, a computer monitor, a projector, a touchscreen display, a liquid crystal display (LCD), a light-emitting diode display, or a flat panel display, for example.

Computing device 500 may include an audio output device 504 (or corresponding interface circuitry, as discussed above). Audio output device 504 may include any device that generates an audible indicator, such as speakers, headsets, or earbuds, for example.

Computing device 500 may include an audio input device 510 (or corresponding interface circuitry, as discussed above). Audio input device 510 may include any device that generates a signal representative of a sound, such as microphones, microphone arrays, or digital instruments (e.g., instruments having a musical instrument digital interface (MIDI) output).

Computing device 500 may include a global positioning system (GPS) device 509 (or corresponding interface circuitry, as discussed above). GPS device 509 may be in communication with a satellite-based system and may receive a location of computing device 1800, as known in the art.

Computing device 500 may include another output device 505 (or corresponding interface circuitry, as discussed above). Examples include an audio codec, a video codec, a printer, a wired or wireless transmitter for providing information to other devices, or an additional storage device.

Computing device 500 may include another input device 511 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 500 may include a security interface device 512. Security interface device 512 may include any device that provides security measures for computing device 500 such as intrusion detection, biometric validation, security encode or decode, managing access lists, malware detection, or spyware detection.

Computing device 500, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first examples, an integrated circuit (IC) device package comprises a package substrate including a signal route that extends a lateral length within a top metallization level. The IC device package comprises a routing structure to couple the package substrate with an IC chip. The routing structure comprises a first metallization feature to couple the signal route with a first IC chip interconnect, and a second metallization feature coupled to a ground plane of the package substrate. The second metallization feature is over at least a portion of the lateral length of the signal route.

In second examples, for any of the first examples the second metallization feature is within a level of the routing structure most proximal to the package substrate.

In third examples, for any of the first through second examples the package substrate comprises a third metallization feature coupled to the ground plane, the third metallization feature under at least a portion of the lateral length of the signal route.

In fourth examples, for any of the first through third examples the routing structure comprises an array of IC chip interconnect interfaces in a level of the routing structure most distal from the package substrate, and the lateral length extends beyond an edge of the array.

In fifth examples, for any of the fourth examples the second metallization feature comprises a contiguous strip of metallization spanning the edge of the array.

In sixth examples, for any of the first through fifth examples the IC chip signal route is a first signal route in the top metallization level, the package substrate further comprises a second signal route adjacent to the first signal rout, and the second metallization feature comprises a contiguous strip of metallization covering at least a portion of both the first and second signal routes.

In seventh examples, for any of the first through sixth examples the IC device package further comprises an IC chip interconnected to metallization features in a level of the routing structure most distal from the package substrate, wherein a first interconnect interface of the IC chip is coupled to the signal route and a second interconnect interface of the IC chip is coupled to the ground plane.

In eighth examples, for any of the seventh examples, the IC device package comprises a package dielectric underfill between the routing structure and the package substrate, wherein a portion of the package dielectric underfill is between the signal route and the second metallization feature.

In ninth examples, for any of the seventh through eighth examples the lateral length extends beyond an edge of the IC chip.

In tenth examples, for any of the seventh through ninth examples the signal route is a first signal route, a third interconnect interface of the IC chip is coupled to a second signal route within the substrate, and the second signal route extends laterally beyond an edge of the IC chip within a metallization level of the package substrate that is between the first signal route and another ground plane of the package substrate.

In eleventh examples, a system comprises a package substrate comprising a signal route that extends a lateral length within a top metallization level, and a plurality of interconnect interfaces within a bottom metallization level. The system comprises an integrated circuit (IC) chip, and a routing structure between the package substrate and the IC chip. The routing structure comprise a first metallization feature coupled to the signal route, and a second metallization feature coupled to a ground plane of the package substrate. The second feature is over at least a portion of the lateral length of the signal route.

In twelfth examples, for any of the eleventh examples the system further comprises a host component coupled to the plurality of interconnect interfaces by a plurality of solder features. The system comprises a power supply coupled to the IC chip through one or more of the interconnect interfaces.

In thirteenth examples, for any of the twelfth examples a terminal of the power supply is coupled to the ground plane of the package substrate.

In fourteenth examples, for any of the eleventh through thirteenth examples the IC chip comprises memory circuitry. The system further comprises a second IC chip adjacent to the first IC chip. The second IC chip is also coupled to the routing structure.

In fifteenth examples, for any of the eleventh through fourteenth examples the package substrate comprises a core, a plurality of front-side metallization levels over a first side of the core, and a plurality of back-side metallization levels over a second side of the core. The top metallization level is one of the front-side metallization levels, and the bottom metallization level is one of the back-side metallization levels.

In sixteenth examples, for any of the eleventh through fifteenth examples the top metallization level is coupled to the routing structure through a plurality of solder interconnects.

In seventeenth examples, for any of the eleventh through sixteenth examples a package dielectric is between the solder interconnects and between the signal route and the second metallization feature.

In eighteenth examples, a method of fabricating an integrated circuit (IC) device package comprises receiving a package substrate comprising a signal route that extends a lateral length within a top metallization level, and a plurality of interconnect interfaces within a bottom metallization level. The method comprises attaching a routing structure to the package substrate, wherein the routing structure comprises a first metallization feature to couple the signal route with a first IC chip interconnect interface, and a second metallization feature to couple to a ground plane of the package substrate. The second metallization feature is over at least a portion of the lateral length of the signal route.

In nineteenth examples, for any of the eighteenth examples an IC chip is coupled to a side of the routing structure opposite the second metallization feature.

In twentieth examples, for any of the eighteenth through nineteenth examples, the method further comprises applying an underfill material between the routing structure and the package substrate, wherein a portion of the underfill material is applied between the signal route and the second metallization feature.

It will be recognized that principles of the disclosure are not limited to the embodiments so described, but instead can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An integrated circuit (IC) device package, comprising:
a package substrate including a signal route that extends a lateral length within a top metallization level; and
a routing structure to couple the package substrate with an IC chip, wherein the routing structure comprises:
a first metallization feature to couple the signal route with a first IC chip interconnect; and
a second metallization feature coupled to a ground plane of the package substrate, wherein the second metallization feature is over at least a portion of the lateral length of the signal route.

2. The IC device package of claim 1, wherein the second metallization feature is within a level of the routing structure most proximal to the package substrate.

3. The IC device package of claim 1, wherein the package substrate comprises a third metallization feature coupled to the ground plane, the third metallization feature under at least a portion of the lateral length of the signal route.

4. The IC device package of claim 1, wherein:
the routing structure comprises an array of IC chip interconnect interfaces in a level of the routing structure most distal from the package substrate; and
the lateral length extends beyond an edge of the array.

5. The IC device package of claim 4, wherein the second metallization feature comprises a contiguous strip of metallization spanning the edge of the array.

6. The IC device package of claim 1, wherein:
the IC chip signal route is a first signal route in the top metallization level;
the package substrate further comprises a second signal route adjacent to the first signal route; and
the second metallization feature comprises a contiguous strip of metallization covering at least a portion of both the first and second signal routes.

7. The IC device package of claim 1, further comprising an IC chip interconnected to metallization features in a level of the routing structure most distal from the package substrate, wherein a first interconnect interface of the IC chip is coupled to the signal route and a second interconnect interface of the IC chip is coupled to the ground plane.

8. The IC device of claim 7, further comprising a package dielectric underfill between the routing structure and the package substrate, wherein a portion of the package dielectric underfill is between the signal route and the second metallization feature.

9. The IC device package of claim 7, wherein the lateral length extends beyond an edge of the IC chip.

10. The IC device package of claim 7, wherein:
the signal route is a first signal route;
a third interconnect interface of the IC chip is coupled to a second signal route within the substrate; and
the second signal route extends laterally beyond an edge of the IC chip within a metallization level of the package substrate that is between the first signal route and another ground plane of the package substrate.

11. A system comprising:
a package substrate comprising:
a signal route that extends a lateral length within a top metallization level; and
a plurality of interconnect interfaces within a bottom metallization level;
an integrated circuit (IC) chip; and
a routing structure between the package substrate and the IC chip, wherein the routing structure comprises:
a first metallization feature coupled to the signal route; and
a second metallization feature coupled to a ground plane of the package substrate, wherein the second feature is over at least a portion of the lateral length of the signal route.

12. The system of claim 11, further comprising
a host component coupled to the plurality of interconnect interfaces by a plurality of solder features; and
a power supply coupled to the IC chip through one or more of the interconnect interfaces.

13. The system of claim 12, wherein:
a terminal of the power supply is coupled to the ground plane of the package substrate.

14. The system of claim 11, wherein the IC chip comprises memory circuitry, and wherein the system further comprises a second IC chip adjacent to the first IC chip, the second IC chip also coupled to the routing structure.

15. The system of claim 11, wherein:
the package substrate comprises a core, a plurality of front-side metallization levels over a first side of the core, and a plurality of back-side metallization levels over a second side of the core;
the top metallization level is one of the front-side metallization levels; and
the bottom metallization level is one of the back-side metallization levels.

16. The system of claim 11, wherein the top metallization level is coupled to the routing structure through a plurality of solder interconnects.

17. The system of claim 16, further comprising a package dielectric between the solder interconnects and between the signal route and the second metallization feature.

18. A method of fabricating an integrated circuit (IC) device package, the method comprising:
receiving a package substrate comprising:
a signal route that extends a lateral length within a top metallization level; and
a plurality of interconnect interfaces within a bottom metallization level; and
attaching a routing structure to the package substrate, wherein the routing structure comprises:
a first metallization feature to couple the signal route with a first IC chip interconnect interface; and
a second metallization feature to couple to a ground plane of the package substrate, wherein the second metallization feature is over at least a portion of the lateral length of the signal route.

19. The method of claim 18, wherein an IC chip is coupled to a side of the routing structure opposite the second metallization feature.

20. The method of claim 18, further comprising applying an underfill material between the routing structure and the package substrate, wherein a portion of the underfill material is applied between the signal route and the second metallization feature.
